(19) United States
(12) Patent Application Publication
(10) Pub. No.: US 2019/0287387 A1
(43) Pub. Date: Sep. 19, 2019

(54) REMOTE CONTROL DEVICE, E.G. FOR REMOTE CONTROL OF A DRONE

(71) Applicant: PARROT DRONES, PARIS (FR)

(72) Inventors: Thibaud KELLER, PARIS (FR); Christine CAUBEL, PARIS (FR)

(21) Appl. No.: 16/298,919

(22) Filed: Mar. 11, 2019

(30) Foreign Application Priority Data
Mar. 13, 2018 (FR) 18 52137

(51) Int. Cl. G08C 17/02; H01Q 1/24; G05D 1/00; H05K 5/02; H01Q 1/12

(52) U.S. Cl. CPC G08C 17/02; H01Q 1/242; G05D 1/0016; B64C 39/024; H01Q 1/1235; G08C 2201/10; G08C 2201/93; H05K 5/0217

(57) ABSTRACT

A remote control device includes a main body and a support assembly configured to receive a mobile electronic device removably and to hold it, the support assembly having a storage configuration and a usage configuration making it possible to receive the mobile electronic device, the remote control device being configured such that the passage from the storage configuration to the usage configuration controls the powering on of the remote control device.

### TECHNICAL FIELD

The present invention relates to the field of remote control devices provided for remotely controlling a remotely controlled apparatus, for example an unmanned aircraft, also called “drone”.

### BACKGROUND

It is possible to provide a remote control device with a support assembly configured to receive an mobile electronic apparatus, such as a mobile telephone or a digital tablet, in order to use a screen of the electronic mobile device for the display, for example, of parameters relative to the remotely controlled apparatus and/or images taken by an image capture apparatus on board the remotely controlled apparatus.

WO2017/177453A1 discloses a remote control device comprising a support assembly for receiving an mobile electronic apparatus such as a mobile telephone, the support assembly having a storage configuration to facilitate transport and a usage configuration in which the support assembly is deployed to receive the electronic mobile device. The remote control device comprises a main body bearing control switches and control buttons. The support assembly comprises a support element mounted sliding on the main body to receive the mobile electronic apparatus between the main body and the support element, or two support elements mounted rotating on the main body and provided to receive the mobile electronic apparatus between them.

Such a remote control device requires many manipulations before it can be used, which makes it complicated to implement.

### SUMMARY OF THE INVENTION

One aim of the invention is to propose a remote control device that is easier to use.

To that end, the invention proposes a remote control device comprising a main body and a support assembly configured to receive a mobile electronic apparatus removably and to hold it, the support assembly having a storage configuration and a usage configuration making it possible to receive the mobile electronic apparatus, the remote control device being configured such that the passage from the storage configuration to the usage configuration controls the powder on of the remote control device.

During the deployment of the support assembly to mount a mobile electronic apparatus on the remote control device, the remote control device is automatically powered on, without the user having to actuate a power button. As a result, the number of operations to be performed by the user to activate the remote control device is reduced, which makes the remote control device easier to use.

In specific embodiments, the remote control device comprises one or several of the following optional features, considered alone or according to all technically possible combinations:
it comprises a switch controlling the powering on/off of the remote control device, the switch being positioned so as to be controlled due to the passage of the support assembly from the storage configuration to the usage configuration;
the switch has a mobile actuating member positioned so as to be actuated due to the passage of the support assembly from the storage configuration to the usage configuration;
the support assembly is connected to the main body by an articulation;
   the actuating member is placed so as to be hidden by the support assembly in the storage configuration;
the actuating member is placed in an indentation arranged in the main body to allow the travel of the support assembly between the storage configuration and the usage configuration;
it comprises a radiocommunication antenna system for sending and/or receiving radio signals, the antenna system being borne by the support assembly;
the passage of the support assembly from the storage configuration to the usage configuration causes the antenna system to be placed in the transmission and/or reception position;
in the storage configuration, the support assembly is folded down against the main body and, in the usage configuration, the support element extends from the main body and away from the main body;
the support assembly has a first part and a second part delimiting a space between them for receiving the mobile electronic apparatus, the first part being mounted movably on the main body to move from the storage configuration to the usage configuration, the second part being mounted movably on the first part so as to adjust the support assembly as a function of dimensions of the mobile electronic apparatus;
it comprises control members situated on the main body and able to be actuated by a user to generate instructions.

### BRIEF DESCRIPTION OF THE DRAWINGS

The invention and its advantages will be better understood upon reading the following description, provided solely as a non-limiting example, and done in reference to the appended drawings, in which:

FIG. 1 is a perspective view of a remote control device provided with a support assembly, the support assembly being in the storage configuration;

FIG. 2 is a perspective view of the remote control device, the support assembly being in the usage configuration;

FIG. 3 is a perspective view of the remote control device, a mobile electronic apparatus being mounted on the support assembly;

FIG. 4 is an exploded perspective view of the remote control device.

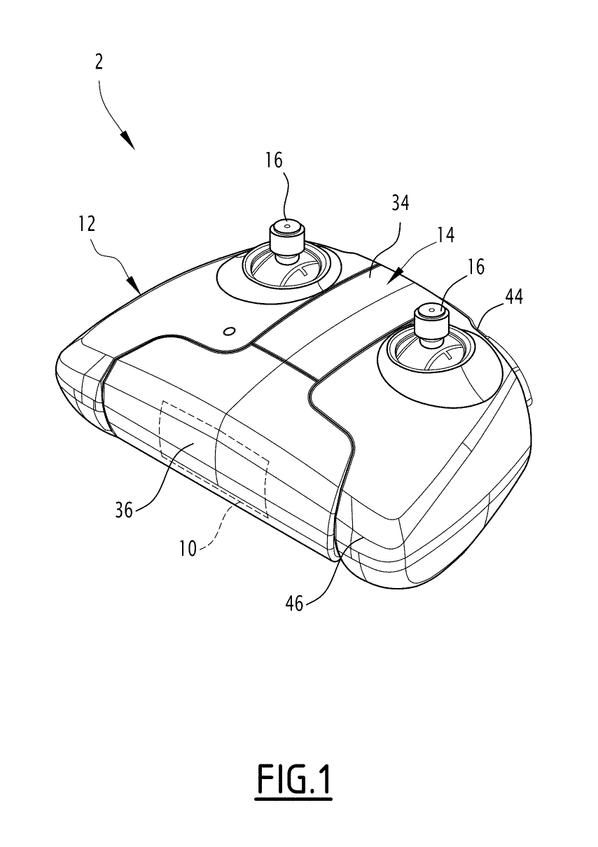

The remote control device 2 of FIGS. 1 to 4 is configured for the remote control of a remotely controlled apparatus 4.

### DETAILED DESCRIPTION OF PREFERRED EMBODIMENTS

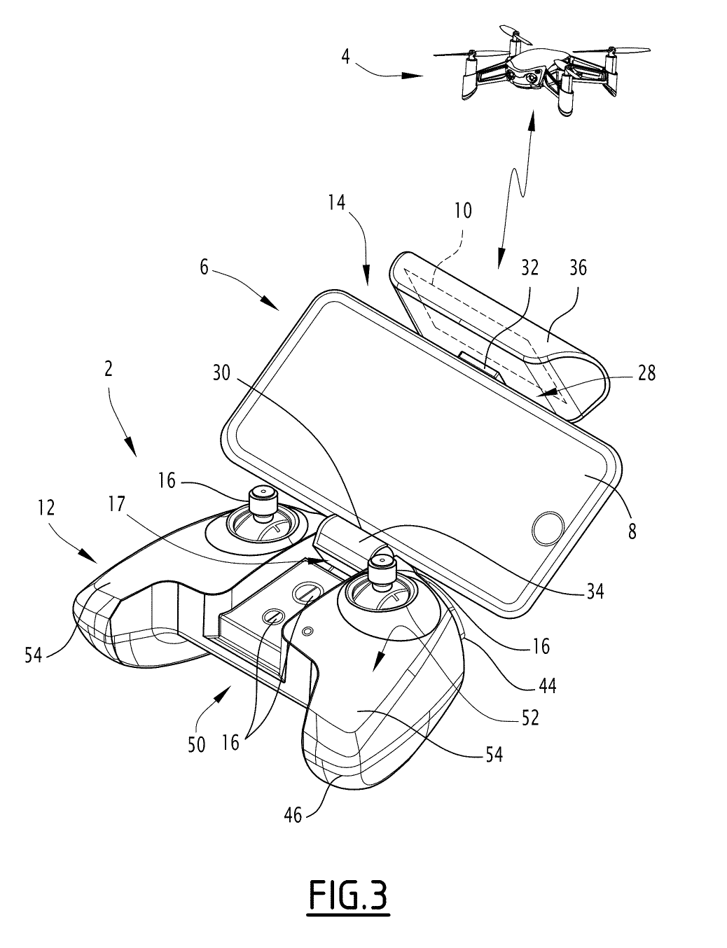

The remotely controlled apparatus 4 is for example a remotely controlled vehicle. As illustrated in FIG. 3, the remotely controlled apparatus 4 is an unmanned aircraft, also called drone, here a rotary-wing drone.

The remote control device 2 is also called “remote control”, and in particular “radio control” when the communication with the remotely controlled apparatus 4 is done by radio waves.

The remote control device 2 is configured to receive a mobile electronic apparatus 6 removably (FIG. 3). The mobile electronic apparatus 6 received on the remote control device 2 is then secured to the latter.

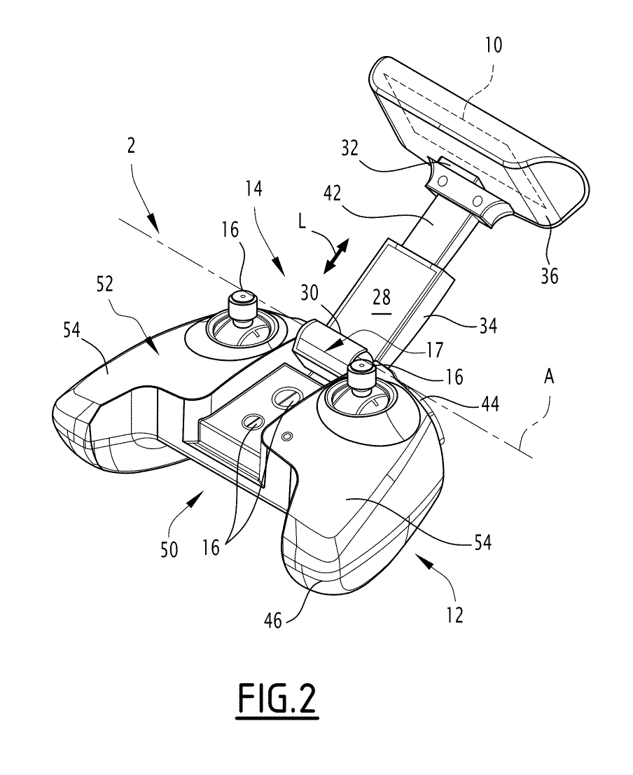

The remote control device 2 has a storage configuration (FIG. 1), in which the remote control device 2 is compact, and a usage configuration (FIGS. 2 and 3), in which the remote control device 2 is able to receive the mobile electronic apparatus 6 removably.

The mobile electronic apparatus 6 is for example a smartphone or a digital tablet.

The mobile electronic apparatus 6 is for example generally in the form of a rectangular slab, at least one of the two opposite faces of the mobile electronic apparatus being provided with a display screen 8 for displaying images.

The mobile electronic apparatus 6 received on the remote control device 2 for example makes it possible to display, on the screen 8, control parameters of the remotely controlled apparatus 4, flight parameters of the remotely controlled apparatus 4, data acquired via sensor on board the remotely controlled apparatus 4 and/or images taken by an image sensor apparatus on board the remotely controlled apparatus 4.

Preferably, the remote control device 2 is configured to establish a communication with the mobile electronic apparatus, by a wired or wireless link, for example a wireless link of the Bluetooth®, Wifi® or near field communication (NFC) link type.

The communication between the remote control device 2 and the mobile electronic apparatus 6 is for example configured so that the remote control device 2 can send data to the mobile electronic apparatus 6 and/or receive data from the mobile electronic apparatus 6. The communication is one-way or two-way.

The remote control device 2 is configured to send signals to the remotely controlled apparatus 4 and/or to receive signals sent by the remotely controlled apparatus 4.

Signals sent to the remotely controlled apparatus 4 are for example control signals of the remotely controlled apparatus 4 or control signals of one or several pieces of equipment on board the remotely controlled apparatus 4, for example a sensor on board the remotely controlled apparatus 4, an image sensor apparatus on board the remotely controlled apparatus 4 and/or an adjustable support by means of which the image capture apparatus is mounted on the remotely controlled apparatus 4.

Signals received from the remotely controlled apparatus 4 are for example signals relative to flight parameters of the remotely controlled apparatus 4 determined for example by an inertial unit of the remotely controlled apparatus 4 or a geolocation receiver integrated into the remotely controlled apparatus 4 and/or images provided by an image acquisition apparatus on board the remotely controlled apparatus 4.

The remote control device 2 is for example configured to send signals to the remotely controlled apparatus 4 and/or to receive signals from the remotely controlled apparatus 4 by radio waves. The remote control device 2 is then a radio control.

The remote control device 2 for example comprises a radiocommunication antenna system 10 for communicating with the remotely controlled apparatus 4 by radio waves.

The antenna system 10 comprises one or several radiocommunication antennas, for example a transceiver antenna, a transmission antenna and/or a reception antenna.

The antenna system 10 for example comprises several different antennas configured for radiocommunications in separate frequency ranges.

The remote control device 2 comprises a main body 12 configured to be grasped by the user during the use of the remote control device 2, and a support assembly 14 configured to receive the mobile electronic apparatus 6 removably.

The main body 12 for example bears control members 16 able to be actuated manually by a user, for example to control the remotely controlled apparatus 4, to control one or several pieces of equipment on board the remotely controlled apparatus 4, to control the remote control device 2 itself and/or to control the mobile electronic apparatus 6 received on the remote control device 2.

The control members 16 for example comprise control levers and/or control buttons.

A control lever for example assumes the form of a joystick mounted pivoting relative to the main body, for example via a pivot link, a swivel link or a Cardan joint.

A control button is for example a pushbutton or a cursor.

The control members 16 here comprise two control levers. Such control members 16 are traditionally used for the remote control of a remotely controlled vehicle 4 such as a drone.

The support assembly 14 is mounted movably on the main body 12 between the storage configuration (FIG. 1), in which the support assembly 14 is moved toward the main body 12 for compact storage of the remote control device 2, and the usage configuration (FIG. 2), in which the support assembly 14 is deployed to receive a mobile electronic apparatus 6.

The support assembly 14 is for example articulated on the main body 12 so as to be folded against the main body 12 in the storage configuration and unfolded away from the main body 12 to be positioned in the usage configuration.

The support assembly 14 is for example articulated on the main body around a rotation axis A, via an articulation 17.

The articulation 17 for example comprises journals 18 received rotating in bearings 20. In the illustrated example, the journals 18 are situated on the support assembly 14 and the bearings 20 are situated on the main body. Alternatively, the positions are reversed.

The remote control device 2 can be selectively powered on (i.e., started or turned on or switched on) or powered off (i.e., stopped or turned off or switched off).

The remote control device 2 is configured such that the passage of the support assembly 14 from the storage configuration to the usage configuration automatically causes the powering on of the remote control device 2 and/or such that the passage of the support assembly 14 from the usage configuration to the storage configuration automatically causes the powering off of the remote control device 2.

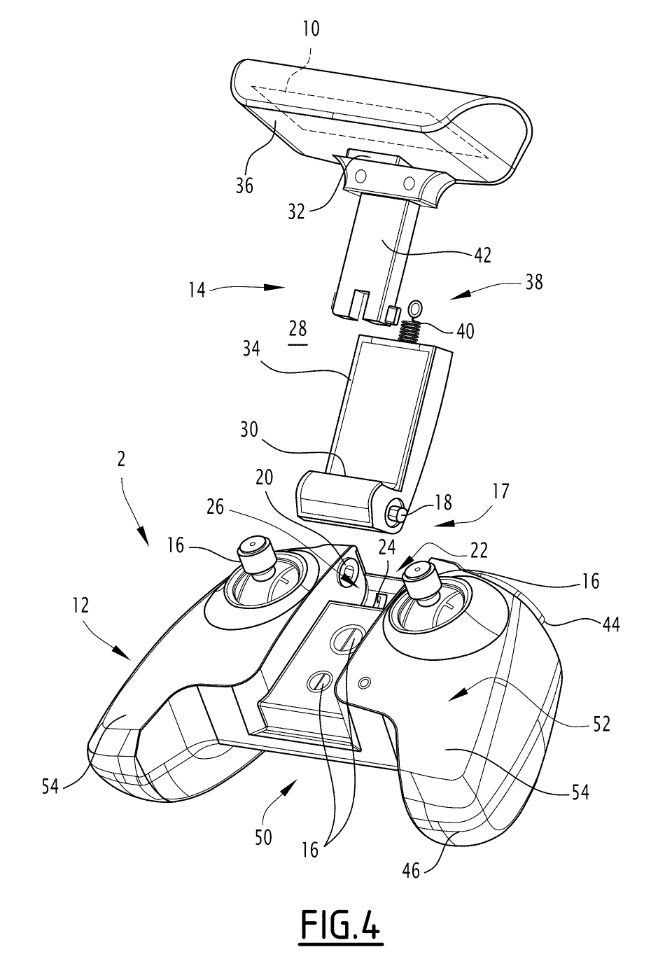

The remote control device 2 here comprises a power switch 22 (FIG. 4) that is positioned so as to be actuated by the support assembly 14 when it moves from the storage configuration to the usage configuration.

The switch 22 here is positioned on the main body 12.

The switch 22 for example comprises an actuating member 24 movable to selectively close or open the switch 22, and thus to power the remote control device 2 on or off.

The switch 22 is positioned such that the actuating member 24 is moved by the support assembly 14 when it moves between the storage configuration and the usage configuration.

Preferably, the actuating member 24 is positioned so as to be covered and hidden by the support assembly 14 at least when the support assembly 14 is in the storage configuration.

The actuating member 24 here is located near the articulation 17 connecting the main body 12 and the support assembly 14. This position allows the switch 22 to be integrated discreetly.

The main body 12 here has an indentation 26 allowing the angular travel of the support assembly 14 relative to the main body 12 during its rotation between the storage configuration and the usage configuration, and the actuating member 24 is positioned in the bottom of said indentation 26.

The actuating member 24 thus positioned is hidden at all times by the support assembly 14.

The support assembly 14 comprises an actuating surface 26 intended to come into contact with the actuating member 24 during the movement of the support assembly 14 relative to the main body 12, so as to actuate the actuating member 24.

In the usage configuration, the support assembly 14 delimits a receiving space 28 for receiving the mobile electronic apparatus 6.

The support assembly 14 is for example configured to hold the mobile electronic apparatus 6 by gripping of the mobile electronic apparatus 6, for example on two opposite edges of the mobile electronic apparatus 6.

The support assembly 14 has a first bearing surface 30 and a second bearing surface 32 substantially facing each other and which are provided to grip the mobile electronic apparatus 6 between them, for example by bearing on opposite edges of the mobile electronic apparatus 6.

Preferably, the support assembly 14 is adjustable so as to be able to vary the distance between the first bearing surface 30 and the second bearing surface 32 as a function of the dimensions of the mobile electronic apparatus 6.

The support assembly 14 comprises a first part 34 and a second part 36 respectively bearing the first bearing surface 30 and the second bearing surface 32, the first part 34 and the second part 36 being translatable relative to one another along an adjustment direction L so as to vary the distance between the first bearing surface 30 and the second bearing surface 32.

The support assembly 14 is moved between the storage configuration and the usage configuration by moving the first part 34 relative to the main body 12, and the support assembly 14 is adjusted as a function of the dimensions of the mobile electronic device 6 by moving the second part 36 in translation relative to the first part 34.

The support assembly 14 comprises a return system 38 configured to bring the first bearing surface 30 and the second bearing surface 32 close to one another. This makes it possible to grip the mobile electronic apparatus 6 automatically between the first bearing surface 30 and the second bearing surface 32.

The return system 38 here is configured to act on the first part 34 and the second part 36 in the direction bringing the first bearing surface 30 and the second bearing surface 32 closer to one another.

The return system 38 for example comprises a return spring 40 (FIG. 4) arranged between the first part 34 and the second part 36 so as to retract the second part 36 toward the first part 34.

The first part 34 and the second part 36 are for example mounted telescoping on one another.

In the illustrated example, the first part 34 is mounted movably on the main body 12, here via the articulation 17, and the second part 36 is mounted telescoping on the first part 34.

The second part 36 is connected to the first part 34 via a connecting element 42 mounted telescoping with the first part 34 along the adjusting direction L.

The connecting element 42 and the first part 34 are fitted and sliding in one another. The connecting element 42 here is fitted and sliding in the first part 34.

The first part 34 has an elongate shape along the adjusting direction L. The first part 34 is connected to the main body at its end opposite the second part 36. The first bearing surface 30 is formed at the end of the first part 34 connected to the main body 12.

The support assembly 14 is generally in the shape of a T, the shaft of which is formed by the first part 34 and the bar of which is formed by the second part 36.

In the illustrated example, the first part 34 is elongated in the adjusting direction L and the second part 36 is elongated perpendicular to the adjusting direction L.

In one possible alternative, the support assembly 14 is generally in the shape of a Y, the shaft of which is formed by the first part 34 and the two arms of which are formed by two portions of the second part 36 diverging from one another.

The main body 12 here has a front edge 44 provided to be oriented forward (from the user's point of view) when the user is holding the remote control device 2 appropriately, and a rear edge 46.

The support assembly 14 is configured such that the mobile electronic apparatus 6 received in the support assembly 14 extends along the front edge 44. This allows an ergonomic arrangement of the mobile electronic apparatus 6, in front of the users hands.

The support assembly 14 is for example articulated on the main body 12 via the articulation 17 positioned along the front edge 46 of the main body 12.

The support assembly 14 in the storage configuration is folded down against the main body 12 to limit the bulk of the remote control device 2, and thus to allow compact storage and easy transport.

As illustrated in FIGS. 1 to 4, optionally, the main body 12 and the support assembly 14 are provided to fit in one another in the storage configuration.

The support assembly 14 here is configured to fit in a receiving housing 50 delimited in the main body 12 in the storage configuration. This favors compactness and protects the support assembly 14, for example during the transport of the remote control device 2.

The support assembly 14 here is configured so as to complete an upper face 52 of the main body 12 in the folded down position. The receiving housing 50 is formed in the upper face 52.

Preferably, the receiving housing 50 has a shape substantially complementary to that of the support assembly 14.

The main body 12 here has two side parts 54, each side part 54 forming a gripping handle allowing the user to grasp the main body 12 with two hands, each hand grasping a respective side part 54. The receiving housing 50 is delimited between the two side parts 54.

Each side part 54 for example bears a respective control member 16 in the form of a control lever, the control member 16 being placed in front of the side part such that the user can manipulate the control member 16 using the thumb of the hand grasping said side part 54.

In the storage configuration, the first part 34 of the support assembly 14 is moved against the main body 12 between the two control members 16.

The receiving housing 50 extends here between the front edge 44 of the main body 12 and the rear edge 46 of the main body 12.

In the illustrated example, the receiving housing 50 emerges on the rear edge 46. The rear edge 46 has a recess formed by the receiving housing 50. This recess facilitates the gripping of the side parts 54 by the user.

The general “T” or “Y” shape of the support assembly 14 articulated on the main body 12 by the base of its shaft makes it possible to have a support assembly 14 that can be situated in front of the main body 12 in the usage configuration, which is ergonomic, while being folded toward the rear of the main body 12 in the storage configuration, the shaft here folding down on the main body 12 between control members 16 for example provided in the form of control levers, the bar or the arms being housed in the rear region of the main body 12.

Optionally, the main body 12 bears one or several control member(s) 16 covered by the support assembly 14 in the storage configuration. The main body 12 here comprises two control members 16 covered by the support assembly 14 in the storage configuration.

Each control member 16 covered by the support assembly 14 and the storage configuration is for example located in the receiving housing 50 of the support assembly 14, in particular on a bottom of the housing 50.

Each control member 16 covered by the support assembly 14 in the storage configuration is for example a pushbutton or a cursor.

As illustrated in FIGS. 1 to 4, the antenna system 10 is supported by the support assembly 14 so as to be deployed when the support assembly 14 is in the usage configuration.

This makes it possible to deploy the antenna system 10 due to the deployment of the support assembly 12, which makes it possible to obtain a remote control device 2 able to be stored compactly, while limiting the number of operations necessary to deploy the remote control device 2. The use of the remote control device 2 is therefore made easier for the user.

The antenna system 10 is preferably located at the end of the support assembly 14 opposite its end connected to the main body 12. Thus, in the deployed configuration, the antenna system 10 is remote from the main body 12 and the user and is situated above the mobile electronic apparatus 6. This results in fewer disruptions to radio communications done via the antenna system 10.

The antenna system 10 is for example carried by the second part 36 of the support assembly 14.

The antenna system 10 is for example carried by the bar of the generally T-shaped support assembly 14 or by one of the arms or both arms of the generally Y-shaped support assembly 14. This arrangement makes it possible to orient the antenna system 10 appropriately for good radiocommunications.

The antenna system 10 carried by the support assembly is advantageously independent of the powering on and/or off of the remote control device 2 automatically due to the movement of the support assembly 14 between the storage configuration and the usage configuration.

Thus, the invention also generally relates to a remote control device 2 by radio frequency (or radio control) signals, the remote control device 2 comprising a main body 12, a support assembly 14 configured to receive a mobile electronic device 16 to keep it secured to the main body 12, the support assembly 14 being mounted movably on the main body 12 between a storage configuration and a usage configuration making it possible to receive the movable electronic apparatus 6, and a radiofrequency antenna system 10 for sending and/or receiving radio frequency signals, the antenna system 10 being carried by the support assembly 14 so as to be deployed during the passage from the storage configuration to the usage configuration.

According to one specific embodiment, such a remote control device 2 may comprise one or several of the following features, considered individually or according to all technically possible combinations:
in the usage configuration, the support assembly 14 has an end connected to the main body 12 and a free end that are opposite one another, the antenna system 10 being situated near the free end of the support assembly 14;
in the usage configuration, the support assembly 14 extends cantilevered from the main body 12;
the support assembly 14 is generally in the shape of a T, the shaft of which is connected at its base to the main body 12 and extends, in the usage configuration, cantilevered from the main body 12, the antenna system 10 being carried by the bar of the T shape.
the support assembly 14 is generally in the shape of a Y, the shaft of which is connected at its base to the main body 12 and extends, in the usage configuration, cantilevered from the main body 12, the antenna being carried by one of the arms or both of the arms of the Y shape.

The generally T-shaped or Y-shaped support assembly 14 articulated at the base of its shaft on the main body 12 is advantageously independent of the powering on and/or off of the remote control device 2 automatically due to the movement of the support assembly 14 between the storage configuration and the usage configuration and the positioning of the antenna system 10 on the support assembly 14, in particular on the bar of the generally T-shaped support assembly or on one of the arms or both arms of the generally Y-shaped support assembly.

Thus, the invention also generally relates to a remote control device 2 comprising a main body 12, a support assembly 14 configured to receive a mobile electronic device 6 and to keep it secured to the main body, the support assembly 14 being mounted movably on the main body 12 between a storage configuration and a usage configuration making it possible to receive the movable electronic apparatus 6, the support assembly 14 being generally in the shape of a T or Y, the base of the shaft of the support assembly 14 being connected to the main body 12 for the movement between the storage configuration and the usage configuration.

According to specific embodiments, such a remote control device 2 may comprise one or several of the following features, considered individually or according to all technically possible combinations:
the shaft is articulated at its base on the main body 12;
the shaft extends, in the usage configuration, cantilevered from the main body 12;
the support assembly is generally in the shape of a T, the bar of which is situated at the end of the shaft opposite the main body 12;
the support assembly is generally in the shape of a Y, the arms of which are situated at the end of the shaft opposite the main body 12;
the support assembly 14 has a first bearing surface 30 and a second bearing surface 32 that are respectively situated at the base of the shaft and on the bar in the case of a general T shape or on one of the arms or on both of the arms in the case of a general Y shape;
the bar is mounted telescoping on the shaft or the arms are mounted telescoping on the shaft to make it possible to adapt the support assembly based on the dimensions of the electronic apparatus received in the support assembly;
in the storage configuration, the shaft and/or the bar or the arms fit in a receiving housing arranged in the main body 12;
the main body 12 bears two control members 16 situated on either side of the support assembly 14 folded down on the main body 14, the shaft passing between the two control members 16;
in the usage configuration, the support assembly 14 extends in front of the main body 12, the shaft rejoining the main body 12 near a front edge of the main body.

The invention is not limited to the example embodiments described above. Alternatives can be considered.

In one possible alternative, the switch 22 comprising a mobile actuating member 24 is replaced by a switch 22 with magnetic control, the opening and closing of which are commanded based on the position of a magnet relative to the switch 22.

The switch 22 for example positioned on one of the body 12 and the support assembly 14, the magnet being positioned on the other, such that the magnet approaches the switch 22 during the closing of the support assembly 14 to command the powering off of the remote control device 2, and moves away from the switch 22 during the closing of the support assembly 14 to command the powering on of the remote control device 2. In one particular example embodiment, the switch 2 is for example positioned on the main body, the control magnet being positioned on the support assembly 14.

1. A remote control device comprising a main body and a support assembly configured to receive a mobile electronic apparatus removably and to hold it, the support assembly having a storage configuration and a usage configuration making it possible to receive the mobile electronic apparatus, the remote control device being configured such that the passage from the storage configuration to the usage configuration controls the powering on of the remote control device.

2. The remote control device according to claim 1, comprising a switch controlling the powering on/off of the remote control device, the switch being positioned so as to be controlled due to the passage of the support assembly from the storage configuration to the usage configuration.

3. The remote control device according to claim 2, wherein the switch has a mobile actuating member positioned so as to be actuated due to the passage of the support from the storage configuration to the usage configuration.

4. The remote control device according to claim 3, wherein the actuating member (24) is placed so as to be hidden by the support assembly in the storage configuration.

5. The remote control device according to claim 3, wherein the actuating member is placed in an indentation arranged in the main body to allow the travel of the support assembly between the storage configuration and the usage configuration.

6. The remote control device according to claim 1, wherein the support assembly is connected to the main body by an articulation.

7. The remote control device according to claim 1, comprising a radiocommunication antenna system for sending and/or receiving radio signals, the antenna system (10) being borne by the support assembly.

8. The remote control device according to claim 7, wherein the passage of the support assembly from the storage configuration to the usage configuration causes the antenna system to be placed in the transmission and/or reception position.

9. The remote control device according to claim 1, wherein, in the storage configuration, the support assembly is folded down against the main body and, in the usage configuration, the support element extends from the main body and away from the main body.

10. The remote control device according to claim 1, wherein the support assembly has a first part and a second part delimiting a space between them for receiving the mobile electronic apparatus, the first part being mounted movably on the main body to go from the storage configuration to the usage configuration, the second part being mounted movably on the first part so as to adjust the support assembly as a function of dimensions of the mobile electronic apparatus.

11. The remote control device according to claim 1, comprising control members situated on the main body and able to be actuated by a user to generate instructions.
